(19) United States
(12) Patent Application Publication
(10) Pub. No.: US 2024/0023298 A1
(43) Pub. Date: Jan. 18, 2024

(54) ELECTRONIC DEVICE AND METHOD FOR MANUFACTURING ELECTRONIC DEVICES

(71) Applicant: InnoLux Corporation, Miao-Li County (TW)

(72) Inventors: Li-Wei SUNG, Miao-Li County (TW); Shun-Yu CHANG, Miao-Li County (TW)

(21) Appl. No.: 18/333,180

(22) Filed: Jun. 12, 2023

(30) Foreign Application Priority Data
Jul. 12, 2022 (CN) 202210817920.7

(51) Int. Cl. H05K 9/00; B41M 3/00

(52) U.S. Cl. CPC H05K 9/00; B41M 3/003; B41J 2/01

(57) ABSTRACT

An electronic device includes a substrate and a light shielding layer. The light shielding layer is arranged on the substrate. The light shielding layer has an edge, a main body area, and a peripheral area between the edge and the main body area, wherein a light penetration rate of the light shielding layer in the peripheral area is greater than a light penetration rate of the light shielding layer in the main body area.

### CROSS-REFERENCE TO RELATED APPLICATIONS

This application claims the benefits of the Chinese Patent Application Serial Number 202210817920.7, filed on Jul. 12, 2022, the subject matter of which is incorporated herein by reference.

### BACKGROUND

### Field of the Disclosure

The present disclosure relates to an electronic device and a method for manufacturing electronic devices.

### Description of Related Art

The trend of panel design of current electronic devices moves toward large sizes, curved surfaces and irregular shapes. In the manufacturing process of electronic devices, an inkjet process can be used to perform inkjet on the protective cover surface of the electronic device. However, in the existing inkjet process, the inkjet quality at the edge of the ink is often poor, and thus is likely to have an aliasing phenomenon, resulting in poor consumer perception.

In order to improve the aliasing phenomenon, it is necessary to change the inkjet stroke and inkjet speed to improve the inkjet quality at the edge. However, this change often greatly increases the inkjet time, and thus affects the production capacity and production cost of the machine, which cannot satisfy the actual requirements.

Therefore, it is desirable to provide an improved electronic device and an improved method for manufacturing electronic devices to mitigate and/or obviate the aforementioned problems.

### SUMMARY

The present disclosure provides an electronic device and a method for manufacturing electronic devices to solve the aforementioned problems.

In one aspect of the present disclosure, there is provided an electronic device, which includes: a substrate; and a light shielding layer arranged on the substrate and provided with an edge, a main body area, and a peripheral area disposed between the edge and the main body area, wherein a light penetration rate of the light shielding layer in the peripheral area is greater than a light penetration rate of the light shielding layer in the main body area.

In another aspect of the present disclosure, there is provided a method for manufacturing electronic devices, which includes: providing a substrate; and forming a light shielding layer on a surface of the substrate, wherein the light shielding layer has an edge, a main body area, and a peripheral area disposed between the edge and the main body area, and a light penetration rate of the light shielding layer in the peripheral area is greater than a light penetration rate of the light shielding layer in the main body area.

Other novel features of the disclosure will become more apparent from the following detailed description when taken in conjunction with the accompanying drawings.

### BRIEF DESCRIPTION OF DRAWINGS

FIG. 1 is a schematic diagram of the electronic device according to an embodiment of the present disclosure;

FIG. 2 is an enlarged schematic view illustrating an edge portion of ink area of a light shielding layer according to an embodiment of the present disclosure;

FIG. 3 shows a flowchart of the method for manufacturing electronic devices of the present disclosure;

FIG. 4 is a schematic diagram of forming a light shielding layer according to the flowchart;

FIG. 5A is a schematic diagram of forming a light shielding layer by inkjet according to an embodiment of the present disclosure;

FIG. 5B is a schematic diagram of forming a light shielding layer by inkjet according to another embodiment of the present disclosure; and

FIG. 5C is a schematic diagram of forming a light shielding layer by inkjet according to still another embodiment of the present disclosure.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to “comprise”, “have”, “include” an element, it means that the component may include one or more of the elements, and the component may include other elements at the same time, and it does not mean that the component has only one of the element, except otherwise specified.

Moreover, in the present specification, the ordinal numbers, such as “first” or “second”, are only used to distinguish a plurality of elements having the same name, and it does not means that there is essentially a level, a rank, an executing order, or an manufacturing order among the elements, except otherwise specified. The ordinal numbers of the elements in the specification may not be the same in claims. For example, a “second” element in the specification may be a “first” element in the claims.

In the present specification, except otherwise specified, the feature A “or” or “and/or” the feature B means only the existence of the feature A, only the existence of the feature B, or the existence of both the features A and B. The feature A “and” the feature B means the existence of both the features A and B.

Moreover, in the present specification, the terms, such as “top”, “upper”, “bottom”, “front”, “back”, or “middle”, as well as the terms, such as “on”, “above”, “over”, “under”, “below”, or “between”, are used to describe the relative positions among a plurality of elements, and the described relative positions may be interpreted to include their translation, rotation, or reflection.

Furthermore, the terms recited in the specification and the claims such as “above”, “over”, “on”, “below” or “under” are intended that an element may not only directly contacts other element, but also indirectly contact the other element.

Furthermore, the term recited in the specification and the claims such as “connect” is intended that an element may not only directly connect to other element, but also indirectly connect to other element. On the other hand, the terms recited in the specification and the claims such as “electrically connect” and “couple” are intended that an element may not only directly electrically connect to other element, but also indirectly electrically connect to other element.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those skilled in the art, the background of the present disclosure or the context of the present specification, and should not be read by an ideal or over-formal way.

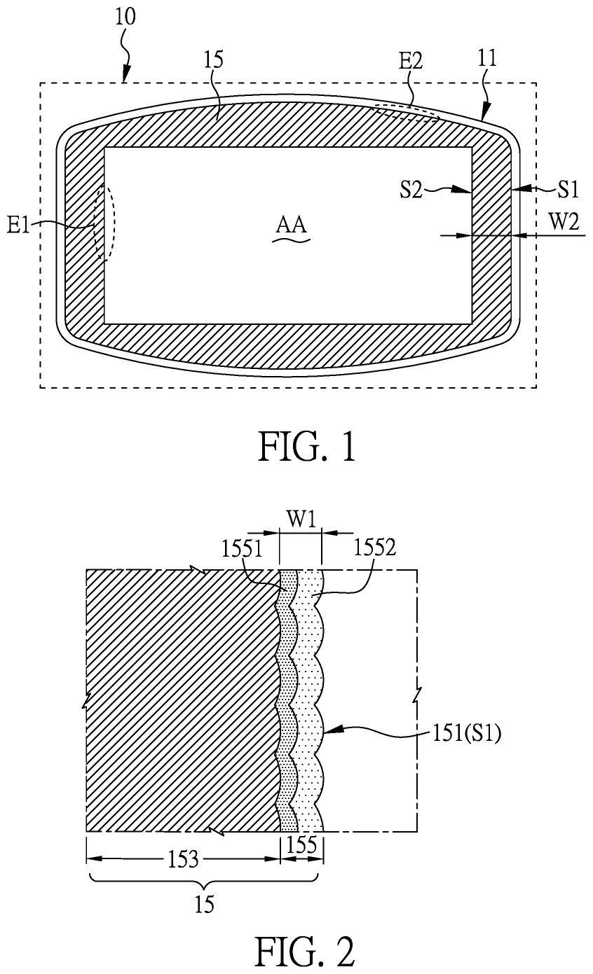

FIG. 1 is a schematic diagram of the electronic device 10 according to an embodiment of the present disclosure, and FIG. 2 is an enlarged schematic view illustrating an edge portion of ink area (for example, area E1) of the light shielding layer 15 according to an embodiment of the present disclosure. The electronic device 10 includes a substrate 11 and a light shielding layer 15. As shown, the substrate 11 may be, for example, a non-rectangular protective cover glass, but it is not limited thereto. The light shielding layer 15 is disposed on the substrate 11; for example, the light shielding layer 15 shields the peripheral portion of the substrate 11 and exposes the active area AA of the electronic device 10.

In the present disclosure, the electronic device 10 may be an electronic device that needs to display images, for example, a display device, a mobile phone, a notebook computer, a video camera, a camera, a music player, a mobile navigation device, a television set, etc., but the present disclosure is not limited thereto. In some embodiments, the electronic device 10 may include a panel (not shown), such as a touch sensing panel, a fingerprint sensing panel, a display panel, an antenna panel, etc. The active area AA is provided as the exposed activating area of the panel. It is noted that, in these embodiments, the substrate 11 in the present disclosure may be arranged above the panel to protect the panel. In addition, the light shielding layer 15 may be disposed between the substrate 11 and the panel, so as to reduce the situation of light leakage caused by part of the light shielding layer 15 falling off due to factors such as scratches.

In the present disclosure, the light shielding layer 15 is formed by inkjet and, as shown in FIG. 2, the edge portion of ink area (area E1 or area E2 in FIG. 1) where the light shielding layer 15 is subject to a gradient transmittance design, wherein the light shielding layer 15 has an edge 151, a main body area 153, and a peripheral area 155 disposed between the edge 151 and the main body area 153. Because the ink at the edge portion of ink area (for example, area E1) is subject to the gradient transmittance design, the light penetration rate of the light shielding layer 15 in the peripheral area 155 may be made to be greater than the light penetration rate of the light shielding layer 15 in the main body area 153. It is noted that, in the present disclosure, the light penetration rate may be measured by placing a light source behind the portion of the substrate 11 that has no light shielding layer 15 coated on the surface thereof, then measuring the brightness from the front of the substrate corresponding to the light source to obtain the first brightness, then placing again the same light source on the portion of the substrate 11 that has the shielding layer 15 coated on the surface thereof, and measuring again the brightness from the front of the substrate corresponding to the light source to obtain the second brightness. The ratio of the second brightness to the first brightness is the light penetration rate (light penetration rate=second brightness/first brightness).

In one embodiment of the present disclosure, the edge 151 of the light shielding layer 15 has a continuous wave shape, but it is not limited thereto. The width W1 of the peripheral area 155 may be 0.3 to 1 mm, and the ratio of the width W1 of the peripheral area 155 to the width W2 (as marked in FIG. 1) of the portion of the light shielding layer that covers the substrate 11 may be in the range of 0.004 to 0.4 (0.004≤W1/W2≤0.4), but it is not limited thereto. It is noted that the width ratio here refers to the ratio of the width W1 of the peripheral area 155 to the width W2 of the light shielding layer 15 on a certain side of the light shielding layer 15. More specifically, in the present disclosure, by taking any three points on the edge 151, the width W1 of the peripheral region 155 on a specific side may be an average value of the shortest distances from the three points to the main body area 153. Similarly, by taking any three points on the edge 151, the width W2 of the light shielding layer 15 on the specific side may be an average value of the shortest distances from the three points to the edge of the opposite side of the light shielding layer (for example, when taking the measurement points on the edge of the side S1 side in FIG. 1, the edge of the opposite side is disposed on the side S2). In some embodiments, the peripheral area 155 may be divided into a plurality of sub-areas, such as the first area 1551 and the second area 1552 shown in FIG. 2, wherein the first area 1551 is closer to the main body area 153 than the second area 1552 and has a lower light penetration rate, and the difference in the light penetration rate between the first area 1551 and the second area 1552 is between 5% and 50% (5%≤light penetration rate difference≤50%). In other embodiments, the difference in the light penetration rate between the first area 1551 and the second area 1552 is between 20% and 40% (20% light penetration rate difference≤40%). In addition, in the present disclosure, the peripheral area 155 may also be divided into three, four, five or more sub-areas, which is not limited in the present disclosure.

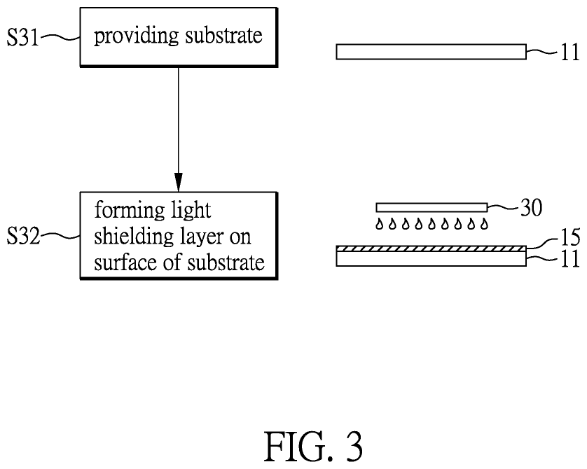

In the manufacture of the electronic device of the present disclosure, the light shielding layer 15 is formed on the substrate 11 by inkjet. FIG. 3 shows a flowchart of the method for manufacturing electronic devices of the present disclosure. As shown, in step S31, first, a substrate 11 is provided, and then, in step S32, a light shielding layer 15 is formed on a surface of the substrate 11.

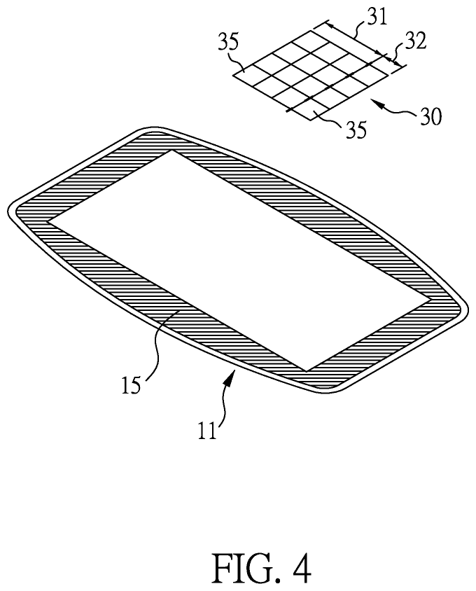

FIG. 4 is a schematic diagram of forming the light shielding layer 15 in the aforementioned step S32, wherein, in the step S32, an inkjet head 30 is used to perform inkjet on the substrate 11 to form the light shielding layer 15 on the surface of the substrate 11. The inkjet head 30 includes, for example, include a plurality of nozzles 35 arranged in a matrix. The inkjet head 30 may be divided into two areas, such as a first inkjet area 31 and a second inkjet area 32. With reference to FIG. 4 and FIG. 2 at the same time, when the inkjet head performs inkjet on the edge portion of the light shielding layer 15, the first inkjet area 31 may correspond to the main body area 153 of the light shielding layer 15, and the second inkjet area 32 may correspond to the peripheral area 155 of the light shielding layer 15. That is, the main body area 153 of the light shielding layer 15 is mainly formed by the nozzles 35 in the first inkjet area 31, and the peripheral area 155 of the light shielding layer 15 is mainly formed by the nozzles 35 in the second inkjet area 32, but it is not limited thereto. For example, when the peripheral area 155 is further divided into a plurality of sub-areas 1551 and 1552 as shown in FIG. 2, the inkjet head can be further divided into more inkjet areas so that different inkjet areas may respectively correspond to different sub-areas in the peripheral area 155.

In the aforementioned inkjet process, the nozzles 35 may be moved while performing inkjet, or moved to a fixed point and then perform inkjet. The position of ink ejected from the first inkjet area 31 may partially overlap the position of ink ejected from the second inkjet area 32 and, after the inkjet is completed, baking and curing are performed to form the light shielding layer 15. In addition, the second inkjet area 32 may be at least one row of nozzles 35 disposed on one side of the inkjet head 30, but the present disclosure is not limited thereto. The second inkjet area 32 may be at least one row of nozzles 35 disposed on one or multiple sides of the inkjet head 30, while the actual arrangement may be determined according to the shape of the light shielding layer 15.

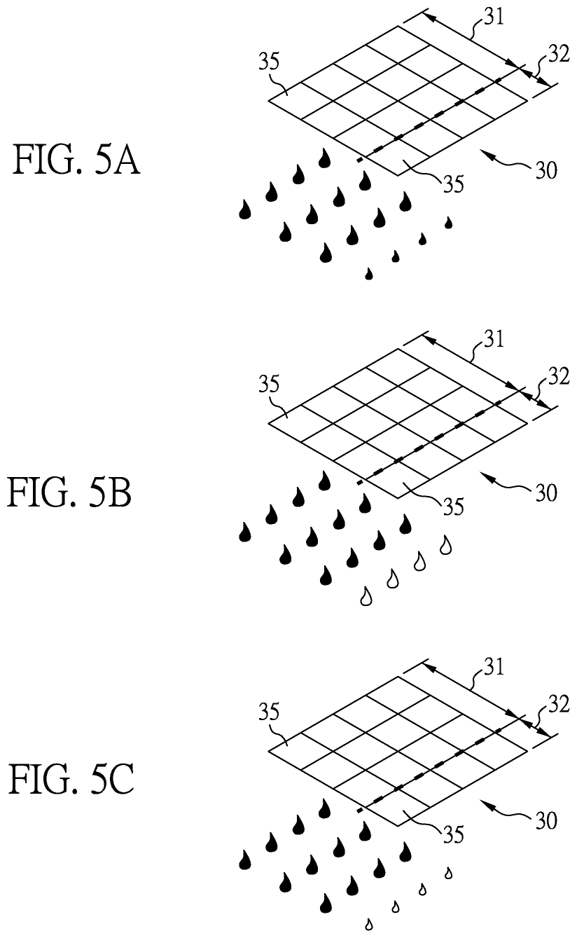

In order to enable the ink at the edge portion of ink area of the light shielding layer 15 to have a gradient transmittance, in one embodiment of the present disclosure, as shown in FIG. 5A, when the inkjet head 30 performs inkjet on the substrate 11, the inkjet amount of one nozzle 35 in the first inkjet area 31 of the inkjet head 30 is more than the inkjet amount of one nozzle 35 in the second inkjet area 32. As a result, the main body area 153 of the light shielding layer 15 formed by inkjet from the nozzles 35 in the first inkjet area 31 receives a relatively large inkjet amount and thus its transmittance is relatively low, and the peripheral area 155 of the light shielding layer 15 formed by inkjet from the nozzles 35 in the second inkjet area 32 receives a relatively small inkjet amount and thus its transmittance is relatively high, so that the gradient transmittance design can be realized.

Furthermore, in another embodiment of the present disclosure, as shown in FIG. when the inkjet head 30 performs inkjet on the substrate 11, the light penetration rate of the ink used by the nozzles 35 in the first inkjet area 31 of the inkjet head 30 is lower than the light penetration rate of the ink used by the nozzles 35 in the second inkjet area 32. As a result, the main body area 153 of the light shielding layer 15 formed by inkjet from the nozzles 35 in the first inkjet area 31 receives ink with a relatively low light penetration rate and thus its transmittance is relatively low, and the peripheral area 155 of the light shielding layer 15 formed by inkjet from the nozzles 35 in the second inkjet area 32 receives ink with a relatively high light penetration rate and thus its transmittance is relatively high, so that the gradient transmittance design can be realized. Similarly, when the peripheral area 155 is further divided into the first area 1551, the second area 1552 or even more sub-areas, the inkjet head can be further divided into more inkjet areas, and inks with different light penetration rates may be used in different inkjet areas to achieve the gradient transmittance design.

Furthermore, in still another embodiment of the present disclosure, as shown in FIG. 5C, when the inkjet head 30 performs inkjet on the substrate 11, the inject amount of one nozzle 35 in the first inkjet area 31 of the inkjet head 30 is more than the inkjet amount of one nozzle 35 in the second inkjet area 32, and the light penetration rate of the ink used in the first inkjet area 31 of the inkjet head 30 is lower than the light penetration rate of the ink used in the second inkjet area 32. As a result, the main body area 153 of the light shielding layer 15 formed by inkjet from the nozzles 35 in the first inkjet area 31 receives a relatively large inkjet amount and receives ink with a relatively low light penetration rate so that its transmittance is relatively low, and the peripheral area 155 of the light shielding layer 15 formed by inkjet from the nozzles 35 in the second inkjet area 32 receives a relatively small inkjet amount and receives ink with a relatively high light penetration rate so that its transmittance is relatively high, whereby the gradient transmittance design can be realized.

As can be seen from the above description, in the present disclosure, when the inkjet head 30 performs inkjet on the substrate 11 to form the light shielding layer 15, by using different amounts of inkjet and/or different light penetration rates of inks, the light penetration rate of the peripheral area 155 of the light shielding layer 15 can be made to be lower than the light penetration rate of the main body area 153, so as to realize the gradient transmittance design, achieve the ink blurring at the edge of the ink, reduce the visibility of the aliasing phenomenon caused by the poor inkjet quality at the edge of the ink, thereby effectively reducing the problem of poor consumer perception caused by the sharp changes in the contrast color at the aliasing edge.

In the present disclosure, the features in different embodiments of the present disclosure can be mixed to form another embodiment without departing from the spirit and scope of the disclosure as hereinafter claimed.

The aforementioned specific embodiments should be construed as merely illustrative, and not limiting the rest of the present disclosure in any way.

1. An electronic device, comprising:
a substrate; and
a light shielding layer disposed on the substrate and provided with an edge, a main body area, and a peripheral area disposed between the edge and the main body area,
wherein a light penetration rate of the light shielding layer in the peripheral area is greater than a light penetration rate of the light shielding layer in the main body area.

2. The electronic device of claim 1, wherein the peripheral area has a width of 0.3 to 1 mm.

3. The electronic device of claim 1, wherein the edge has a continuous wave shape.

4. The electronic device of claim 1, wherein the peripheral area is divided into a first area and a second area, the first area is closer to the main body area than the second area, and a difference between the light penetration rate of the first area and the light penetration rate of the second area is 5% to 50%.

5. The electronic device of claim 1, wherein a ratio of a width of the peripheral area to a width of the light shielding layer is between 0.004 and 0.4.

6. The electronic device of claim 1, further comprising a panel, wherein the substrate is arranged above the panel.

7. The electronic device of claim 1, wherein the substrate is a protective cover glass.

8. A method for manufacturing electronic devices, comprising:
providing a substrate; and
forming a light shielding layer on a surface of the substrate,
wherein the light shielding layer has an edge, a main body area, and a peripheral area disposed between the edge and the main body area, and a light penetration rate of the light shielding layer in the peripheral area is greater than a light penetration rate of the light shielding layer in the main body area.

9. The method of claim 8, wherein the light shielding layer is formed by using an inkjet head to perform inkjet on the substrate, the inkjet head is divided into a first inkjet area and a second inkjet area, the first inkjet area corresponds to the main body area, and the second inkjet area corresponds to the peripheral area.

10. The method of claim 8, wherein the inkjet head has a plurality of nozzles disposed in the first inkjet area and the second inkjet area, and an inkjet amount of one nozzle in the first inkjet area is more than an inkjet amount of one nozzle in the second inkjet area.

11. The method of claim 8, wherein the inkjet head has a plurality of nozzles disposed in the first inkjet area and the second inkjet area, and a light penetration rate of ink used by the nozzles in the first inkjet area is lower than a light penetration rate of ink used by the nozzles in the second inkjet area.

12. The method of claim 8, wherein the inkjet head has a plurality of nozzles, and the plurality of nozzles eject ink while moving.

13. The method of claim 8, wherein the inkjet head has a plurality of nozzles, and the plurality of nozzles move to a fixed point and then perform inkjet.

14. The method of claim 8, wherein the inkjet head has a plurality of nozzles disposed in the first inkjet area and the second inkjet area, and a position of ink ejected by one nozzle in the first inkjet area partially overlaps a position of ink ejected by one nozzle in the second inkjet area.

15. The method of claim 8, wherein, after completing inkjet, baking and curing are performed to form the light shielding layer.

16. The method of claim 8, wherein the inkjet head has a plurality of nozzles disposed in the first inkjet area and the second inkjet area, an inkjet amount of one nozzle in the first inkjet area is more than an inkjet amount of one nozzle in the second inkjet area, and a light penetration rate of ink used by the nozzles in the first inkjet area 31 is lower than a light penetration rate of ink used by the nozzles in the second inkjet area.

17. The method of claim 8, wherein the peripheral area has a width of 0.3 to 1 mm.

18. The method of claim 8, wherein the edge has a continuous wave shape.

19. The method of claim 8, wherein the peripheral area is divided into a first area and a second area, the first area is closer to the main body area than the second area, and a difference between the light penetration rate of the first area and the light penetration rate of the second area is 5% to 50%.

20. The method of claim 8, wherein a ratio of a width of the peripheral area to a width of the light shielding layer is between 0.004 and 0.4.
